(19) United States
(12) Patent Application Publication
(10) Pub. No.: US 2005/0005216 A1
(43) Pub. Date: Jan. 6, 2005

(54) Electronic component

(76) Inventors: Majid Ghameshlu, A-Wien (AT); Karlheinz Krause, Planegg (DE)

Correspondence Address: Siemens Corporation;Intellectual Property Department, 170 Wood Avenue South, Iselin, NJ, 08830, US

(21) Appl. No.: 10/490,572

(22) PCT Filed: Aug. 30, 2002
(86) PCT No.: PCT/EP02/09690

(30) Foreign Application Priority Data
Sep. 21, 2001 (EP) 01122774.1

(51) Int. Cl. G01R 31/28

(52) U.S. Cl. 714/727

(57) ABSTRACT

The invention relates to an electronic component comprising an integrated circuit that is provided with a core with functional flip-flops. A part of the functional flip-flops are linked as input flip-flops with input pins of the component and a part of the functional flip-flops are linked as output flip-flops with output pins of the component. The aim of the invention is to fulfill high timing requirements while not complicating the verification of timing and logic. For this purpose, the input flip-flops and the output flip-flops are arranged in such a manner that they form at least input block and one output block each with respective clock domains that differ from the clock domains of the remaining core.

### CROSS REFERENCE TO RELATED APPLICATIONS

This application is the US National Stage of International Application No. PCT/EP02/09690, filed Aug. 30, 2002 and claims the benefit thereof. The International Application claims the benefits of European application No. 01122774.1 filed Sep. 21, 2001, both applications are incorporated by reference herein in their entirety.

### FIELD OF INVENTION

The invention relates to an electronic component comprising an integrated circuit which has a core with functional flip-flops, some of the functional flip-flops being connected as input FFs to input pins of the component and some of the functional flip-flops being connected as output FFs to output pins of the component.

### BACKGROUND OF INVENTION

Electrical components of this kind are often designed as application-specific integrated circuits (ASICs). An ASIC is the term used to designate an arrangement of logical gate and memory circuits on a single silicon wafer. ASICs are a collection of circuits having simple functions, such as flip-flops, inverters, NANDs and NORs, as well as more complex structures such as memory arrays, adders, counters and phase locked loops. The different circuits are combined in an ASIC in order to implement a specific application. ASICs are used in a multiplicity of products, including for example consumer products such as video games, digital cameras, in motor vehicles and PCs, as well as in high-end technology products such as workstations and supercomputers.

A known ASIC architecture is illustrated with reference to FIG. 1. The ASIC 1 comprises an ASIC core 2 which contains the various circuit elements which make up the function of the ASIC 1. The ASIC core 2 receives the inputs to be processed from input drivers 3. On completion of processing by the ASIC core 2 the output data is output via output drivers 4.

Various “Design for Test” (DFT) methods are known for testing the functionality of the ASIC. The advantage of DFT methods is that as early as during the chip design phase circuit elements are inserted which permit subsequent scan-based testing, reduce the number of test points required on the board of the ASIC and at the same time get round the problem of access points not being available on the chip.

One of these methods is the “Built-In-Self-Test” (BIST), for which there are provided BIST input cells 5, which are disposed between the input drivers 3 and the ASIC core 2, and BIST output cells 6, which are located between the ASIC core 2 and the output drivers 4. Via the BIST input cells a test vector can be input into the ASIC core 2 in order to test the circuits inside the core along a “scan path”. The outputs from the ASIC core 2 stimulated by the test vector arrive in the BIST output cells 6, which represent the test response evaluator (TAN) for the BIST method.

A further DFT method is what is known as the “boundary scan” (BS), which is based on IEEE Standard 1149-1 and is described in detail for example in the book titled “Boundary Scan Test: A Practical Approach”, H. Bleeker, Klowr Academic Publishers 1993, ISBN 0-7923-9296-5. The boundary scan provides BS input cells 8, which are located between the input drivers 3 and the ASIC core 2, as well as BS output cells 9 between the ASIC core 2 and the output drivers 4, whereby the cells 8, 9 are connected via the connection 7. The purpose of the boundary scan is to test connections and terminals between individual integrated circuits (ICs). In this test the BS input cells 8 and the BIST output cells 6 form shift registers in order to control the output pins of the ASIC and to test input pins of the ASIC.

The increasingly stringent timing requirements for ASICs can at the present time only be met by special measures, such as for example by the use of phase locked loops (PLLs) and clock islands inside the ASIC core during the development of the ASIC. Creating different clock islands produces additional interfaces in the ASIC core 1 which, in terms of timing and logic verification, constitute an extra overhead as well as additional sources of error.

U.S. Pat. No. 6,131,173 discloses an electronic component having logic elements of the core which are distributed over different clock domains and different circuits (seam circuits) in connection with the additional internal interfaces necessary as a result of the different clock domains.

U.S. Pat. No. 6,115,827 discloses arrangements which are used for electronic components also having logic elements of the core which are distributed over different clock domains and for testing thereof. Common to the electronic components disclosed in both U.S. Pat. No. 6,131.173 and U.S. Pat. No. 6,115,827 is that the logic verification is made more difficult because of the internal interfaces.

### SUMMARY OF INVENTION

The object of the present invention is therefore to provide an electronic component which satisfies to high timing requirements, yet does not make the timing and logic verification more difficult.

This object is achieved by an electrical component according to claim 1, wherein the input FFs and the output FFs form at least one input block and one output block respectively, each with separate clock domains which are different from the clock domain of the remainder core.

As a result the critical input/output timing is isolated from the core timing and, by the creation of clock domains, the input/output timing problems are easier to locate and isolate, as well as being more easily controllable and more observable.

According to an advantageous aspect of the present invention, in order to perform a boundary scan (BS) corresponding BS input cells which are disposed in parallel upstream of the input FFs are provided outside of the input block and further BS output cells are provided downstream of the output FFs outside of the output block in order thereby to implement the boundary scan according to IEEE Standard 1149-1.

According to a further advantageous exemplary embodiment of the present invention, in order to perform a built-in self-test (BIST) the input FFs of the input block can be interconnected to form a chain (for this reason the input FFs are implemented as scan FFs), and are fed with test vectors by a test pattern generator during the BIST, and in addition the output FFs of the output block are interconnected to provide a linear feedback shift register (LFSR) and form a test response evaluator (TAA) for the BIST. In the present exemplary embodiment the BIST is thus implemented without the provision of separate BIST input and output cells, as a result of which the number of gates is reduced. On the output side the timing is also rendered less critical, since the draw-off for the BIST output cells is dispensed with.

On the input side the BIST multiplexer that would otherwise be necessary is also omitted, thus improving the timing of the signal input path.

According to another advantageous exemplary embodiment of the present invention, the clock phases of the clock domains of the input FFs and the output FFS are different from the clock phase of the remainder of the core. This simplifies the arrangement of the time-critical “first” and “last” flip-flops, in other words the input FFS and the output FFS in the component layout, since they are all located in the input block or output block and these form a separate unit in the architecture of the component according to the invention.

According to another advantageous exemplary embodiment of the present invention, the clock phases of the clock domains of the input FFS and the output FFs are different from the clock phase of a system clock of the component, as a result of which a simpler arrangement of the elements in the layout is likewise made possible.

According to a particularly advantageous exemplary embodiment of the present invention, the clock domains are each connected via clock modification elements such as phase locked loops and delay elements to a system clock input of the component, by means of which the phases of the individual clock domains can be regulated. In this way a simpler and less time-consuming and costly after treatment of the component environment and a greater transparency are provided. As a result the probability of inappropriate circuit elements being installed is radically reduced and the transparency of the circuit structure increases.

According to another advantageous exemplary embodiment of the present invention, delay elements are disposed in the input block ahead of the input FFs for the purpose of adjusting the hold time of the input FFs.

According to a further advantageous exemplary embodiment of the present invention, delay elements are disposed in the input block after the input FFs and ahead of the remainder core for the purpose of adjusting the clock skew.

According to a further advantageous exemplary embodiment of the present invention, delay elements are disposed in the output block for the purpose of adjusting the min-clock-to-output.

Advantageously, with the last mentioned exemplary embodiments, the delay elements for adjusting the hold time and for adjusting the min-clock-to-output can be installed centrally in the input block and the output block.

### BRIEF DESCRIPTION OF THE DRAWING

An exemplary embodiment of the invention is described in more detail below with reference to the drawings, in which:

FIG. 1 shows an ASIC as described in the foregoing according to a conventional architecture;

FIG. 2 is a schematic representation of an ASIC according to the present invention.

### DETAILED DESCRIPTION OF INVENTION

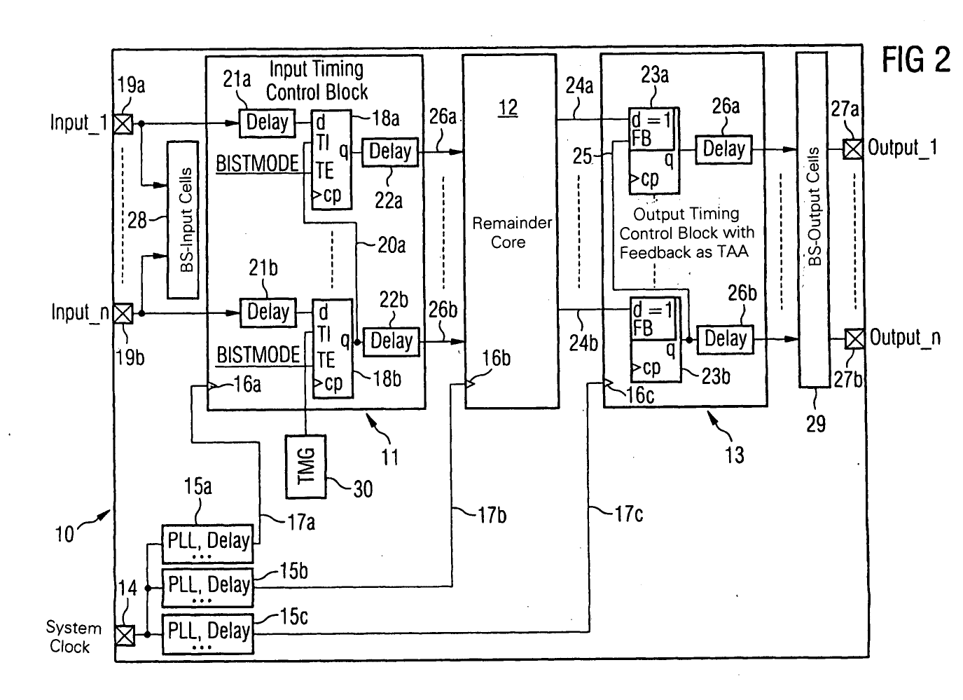

An ASIC 10 according to the present invention is described with reference to FIG. 2. As can be seen from the block diagram shown in FIG. 2, the ASIC 10 according to the invention comprises at least one integrated circuit (IC) which is essentially made up of three blocks, an input timing control block (ITCB) 11 or an input block, a remainder core 12 and an output timing control block (OTCB) or an output block 13.

The three separate blocks 11,12 and 13 are supplied with their clock timing via the terminals 16a, 16b and 16c respectively. The ASIC 10 receives the system clock at a system clock terminal 14. This system clock or input clock received at the system clock terminal 14 is relayed to the blocks 11,12 and 13 via lines 17a, 17b and 17c. Clock modification elements 15a, 15b and 15c are located between the system clock terminal 14 and the respective clock inputs 16a, 16b and 16c. The respective clock modification elements 15a, 15b and 15c comprise delay elements, PLLs or delay locked loops (DLLs) and thus constitute a block-specific timing for the blocks 11,12 and 13. The blocks with the different timing form different clock domains in the ASIC 10. In the preferred exemplary embodiment the clock domains of the blocks 11,12 and 13 have different clock phases. Furthermore, in the preferred exemplary embodiment the clock domains of the input block 11 and the output block 13 differ from that of the remainder core 12, whereby the remainder core 12 forms a different clock domain than the system clock. However, other configurations are also altogether conceivable, for example a configuration in which, as in the previous example, the clock domains of the input block 11 and the output block 13 are different from that of the remainder core 12, but the remainder core 12 is clocked with an unmodified system clock.

Although the preferred exemplary embodiment from FIG. 2 shows only one ITCB 11 and one OTCB 13, both, ITCB 11 and OTCB 13, can perfectly well exist as a plurality of control blocks if that is made necessary due to numerous clock domains on account of the ASIC application.

The circuit elements of the ITCB 11, the remainder core 12 and the OTCB 13 together provide the function of the IC of the ASIC 10. The circuit elements are functional flip-flops (FFs) and other functional elements such as inverters, NANDs and NORs, etc. In the following the term “functional” denotes flip-flops or other circuit elements which are required solely for operation of the ASIC10 and the implementation of its application-specific function. Such flip-flops or circuit elements, such as, for example, the BS input and output cells 5, 6 referred to at the beginning for testing the ASIC 10, are not covered by this term.

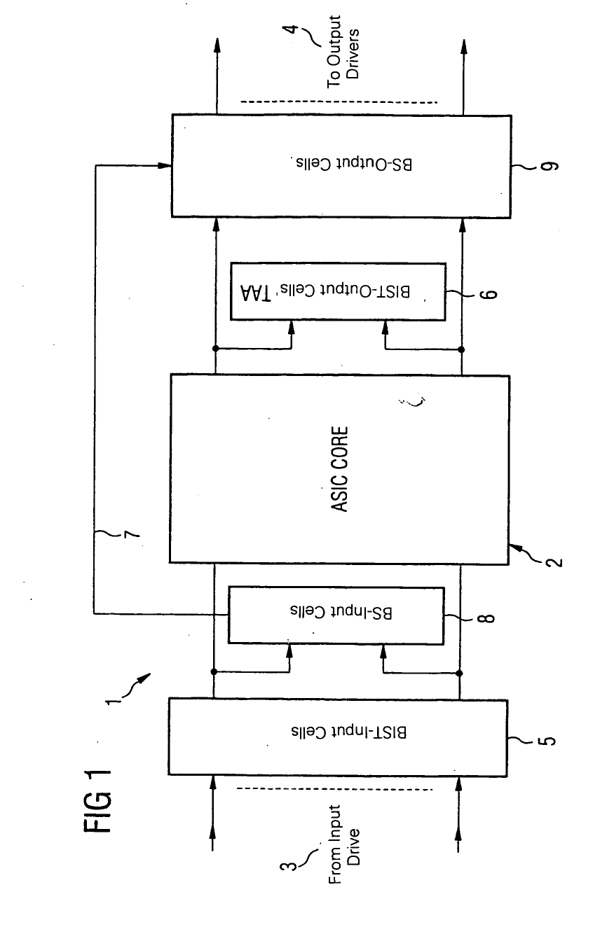

The blocks 11,12 and 13 together comprise the ASIC core 2 described in relation to the prior art (see FIG. 1). The ITCB 11 comprises a plurality of functional flip-flops 18 which are referred to below as input FFs. The input FFs 18 as well as other flip-flops or circuit elements (not shown) contained in the ITCB 11 are functional components of the ASIC core 2 mentioned in relation to the prior art but which are exported into the ITCB 11.

Each input FF 18 is connected at the data input d via an input buffer (not shown here) to a corresponding input pin 19. The output q of an input FF 18 is connected indirectly, i.e. via other circuit components (not shown) of the ITCB 11, or directly to the remainder core 12. In addition, each Input FF 18 has a clock input CP to which the block-specific timing is applied either unmodified, as it is received in the clock input 16a of the ITCB 11, or in a block-internal modified form.

Moreover, each input FF 18a has a tester input TI, which is connected to the output q of an adjacent input FF 18b via line 20. In the input area of each input FF 18 there is a multiplexer (not shown) which has the terminals d and TI as inputs and, depending on its switched state, relays the input either at the terminal d or at the terminal TI to the actual input FF 18. The multiplexer is controlled by means of a control signal which is supplied via a terminal of the scan FF 18, which is designated as tester input TE. The further function of the multiplexer is described below in relation to the built-in self-test (BIST).

It should be noted here that the dashed lines in FIG. 2 are intended to stand schematically for an arbitrary number of ASIC components located above and below the dashed line. In relation to the ITCB 11 this means that an arbitrary number of input FFs 18 are implied, whereby, given appropriate switching of the multiplexer of the input FF 18a, the input TI of each input FF 18a is connected via a line 20 to the output q of the adjacent input FF 18b.

In normal operation the ASIC 10 receives its inputs or input parameters via the input pins 19a, 19b. The inputs are re-timed immediately after the input buffers (not shown) in the ITCB 11 by means of the input FFs 18a, 18b, i.e. the input is transferred into the input FF 18. If necessary first delay elements 21a, 21b can be inserted in the ITCB 11 ahead of a respective input FF 18a, 18b in order to realize the pin input timing. Inserting delay elements 22a, 22b between the ITCB 11 and the remainder core 12 for the purpose of adjusting the clock skew is also possible. The clock skew denotes the bandwidth of the phase shift of the clocks at the clock inputs CP of the input FFs 18 inside the ITCB 11.

The output data of the ITCB 11 are input into the remainder core 12 via lines 26a, 26b for further processing. The processing is performed in the remainder core 12 using a clock timing applied at the clock input 16b. On completion of processing in the remainder core 12 the data is input into the OTCB 13 via lines 24a, 24b.

Like the ITCB 11, the OTCB 13 comprises functional flip-flops which are designated in the following as output FFs 23. The output FFs 23a, 23b, as well as other circuit components present in the OTCB if applicable, are functional components of the ASIC core 10. After the outputs of the remainder core 12 have been input into the OTCB 13, the inputs are re-timed accordingly either indirectly, i.e. via other circuit components of the OTCB 13 (not shown) that are possibly present or directly by means of the output FFS 23a, 23b. Each output FF 23a, 23b has an input d for receiving data from the remainder core 12, as well as an input FB which is connected via a line 25 to the output q of another output FF 23b. An XOR gate with the inputs d and FB as gate inputs is located in the input area of the output FFs 23.

The timing of the output FFS 23 of the OTCB 13 is supplied place in turn via a clock input CP of the output FFS 23, at which input the block-specific timing is applied either unmodified, as it was received in the clock input 16c of the OTCB 12, or in a block-internal modified form.

The output of the output FFS 23 is provided at the output q.

The outputs q are connected to respective output pins 27a, 27b via output buffers (not shown here). Third delay elements 26a, 26b can be provided in the OTCB 13 after the output FFS 23a, 23b for the purpose of adjusting the min-clock-to-output. In normal operation the CRCB 13 therefore supplies the ASIC outputs to the corresponding pins 27.

In the following it will be discussed how the design-for-test (DFT) method, the built-in self-test (BIST) and the boundary scan (BS) referred to at the beginning are implemented in an integrated circuit with the above described architecture comprising a plurality of clock domains.

For the boundary scan, BS input cells 28 are provided after the input pins 19a, 19b and the input buffers. The BS input cells 28 are driven directly by the ASIC input buffers (not shown), since they are disposed parallel to the ITCB 11. Similarly, BS output cells 29 are provided on the output side after the OTCB 13 and ahead of the output buffers (not shown) and the output pins 27a, 27b. All th ASIC outputs are re-timed ahead of the BS output cells 29 in the OTCB 13. The BS output cells or boundary scan cells 29 are located, as required according to the IEEE 1149 standard, between the output FFs 23a, 23b and the output buffers. Thus, the independence of the boundary scan according to IEEE 1149 is guaranteed.

For the BIST, the ASIC 10 is placed into the BIST mode. In the ITCB 11, the input FFs 18a, 18b are interconnected to form a chain in the BIST mode via a BIST MODE signal at the input TE by controlling the multiplexers. In this arrangement the first input FF 18b of the chain is connected via the input TI to a test pattern generator TMG 30. The test pattern generator 30 feeds the chain of input FFs 18a, 18b with a test vector in order t perform the BIST. The conventional BIST input cells (see FIG. 1) ahead of the ASIC core are no longer necessary, since the special BIST functionality of the BIST input cells 28 is also transferred from the mentioned input FFs 18a, 18b. On the output side of the ASIC 10, the output FFs 23a, 23b in the OTCB 13 are interconnected in the BIST mode to provide a linear feedback shift register (LFSR) and form the test response evaluator (TAA). The conventional BIST output cells after the output FFs 23a, 23b are likewise unnecessary, since the output FFs 23a, 23b are interconnected in the BIST mode to form the said LFSR.

The following advantages are produced as a result of the above described architectural approach according to the present invention:

The critical input/output timing is isolated from the core timing. As a result, the input/output timing problems are easier to locate and isolate, as well as being more easily controllable and more observable.

The structured creation of clock islands, as well as of the ITCB 11 and OTCB 13 (on the input and output side) by means of delay elements, PLLs or DLLs, becomes easier, and the aftertreatment of the environment is made less time-consuming and costly and more transparent. The probability of inappropriate circuit elements being installed is radically reduced and the transparency of the circuit structure increases.

The delay elements for adjusting the hold time 21a, 21b or for adjusting the min-clock-to-output 26a, 26b can be installed (centrally) in the ITCB 11 and the OTCB 13.

The BIST input and output cells for the BIST are omitted, thus reducing the number of gates.

As the BIST multiplexer is omitted on the input side, the timing of the signal input path is improved.

The timing on the output side is also rendered less critical, since the draw-off for the BIST output cells is dispensed with.

The arrangement of the time-critical “first” and “last” flip-flops, in other words the input FFs and the output FFs in the ASIC layout, is simplified, since they are all located in the ITCB 11 or OTCB 13 and these form a separate unit in the architecture of the ASIC 10 according to the invention.

The blocks ITCB 11 and OTCB 13 can be subdivided into 8 or 16 sub-blocks like the boundary scan blocks in conventional ASICs. In this way it is possible, in the layout of the ASIC 10, to merge these sub-blocks with the functional blocks in the remainder core 12, i.e. arrange them close together locally, though at the same time maintaining the logical separation. In this way the timing between the edge, i.e. the ITCB 11 and OTCB blocks 11, 13, and the remainder core 12 is made less critical.

To sum up it can be said that the architecture of the present invention presented here permits the ASIC to be configured with regard to different clock domains or clock islands, whereby the BIST is also included (virtually drops away) and makes the conventional BIST input and output cells superfluous, and also takes into account the boundary scan defined according to the 1149 standard. Thus, an optimization of the timing, verification and implementation of the individual components is achieved. In conclusion it should be noted that although the present invention has been described in relation to an ASIC, the present invention can be applied generally for all integrated circuits.

The present invention can also be used in particular in connection with the European patent application 01122773.3 filed on the same date by the same applicant with the title “Electronic component and method for its qualification testing”, whereby in order to avoid repetitions the subject matter of that application is also included in the content of the present application.

1-10. (canceled)

11. An electronic component with an integrated circuit, comprising:
a plurality of input pins;
a plurality of output pins;
a core operatively connected to the integrated circuit, and subdivided into blocks that form different clock domains;
a plurality of functional flip-flops, a portion of the functional flip-flops connected as input flip-flops to input pins of the component and a portion of the functional flip-flops connected as output flip-flops to output pins of the component; and whereby in normal operation inputs are entered into the electronic component via the input pins and the input flip-flops and whereby outputs of the electronic component are exported via the output flip-flops and the output pins; and
a remainder core adapted to provide the circuit elements of the input block, the remainder core and the output block adapted to provide the function of the integrated circuit, the remainder core forming a second clock domain that is different from the first and the third clock domain,
wherein the input flip-flops form at least one input block having a first clock domain, and
wherein the output flip-flops form an output block having a third clock domain, and
wherein a built-in self-test BIST is performed so that the input flip-flops of the input block are interconnected to form a chain into which test vectors are input by a test pattern generator during the BIST, and the output flip-flops of the output block are interconnected to provide a linear feedback shift register and a test response evaluator for the BIST.

12. The component according to claim 11, wherein boundary scan input cells are arranged in parallel upstream of the input flip-flops and outside of the input block, and further boundary scan output cells are provided downstream of the output flip-flops and outside of the output block.

13. The component according to claim 11, wherein the input flip-flops and the output flip-flops are connected respectively via input buffers to the input pins and via output buffers to the output pins.

14. The component according to claim 11, wherein the clock phases of the clock domains of the input flip-flops and the output flip-flops are different from the clock phase of the remainder core.

15. The component according to claim 11, wherein the clock phases of the clock domains of the input flip-flops and the output flip-flops are different from the clock phase of a system clock of the component.

16. The component according to claim 11, wherein the clock domains are each connected via clock modification elements to a system clock input of the component.

17. The component according to claim 11, wherein first delay elements for adjusting the hold time are disposed upstream of the input flip-flops in the input block.

18. The component according to claim 11, wherein second delay elements for adjusting the clock skew are disposed after the input flip-flops and upstream of the remainder core in the input block.

19. The component according to claim 11, wherein third delay elements for adjusting the min-clock-to-output are disposed in the output block.

20. The component according to claim 12, wherein the input flip-flops and the output flip-flops are connected respectively via input buffers to the input pins and via output buffers to the output pins.

21. The component according to claim 12, wherein the clock phases of the clock domains of the input flip-flops and the output flip-flops are different from the clock phase of the remainder core.

22. The component according to claim 13, wherein the clock phases of the clock domains of the input flip-flops and the output flip-flops are different from the clock phase of the remainder core.

23. The component according to claim 12, wherein the clock phases of the clock domains of the input flip-flops and the output flip-flops are different from the clock phase of a system clock of the component.

24. The component according to claim 13, wherein the clock phases of the clock domains of the input flip-flops and the output flip-flops are different from the clock phase of a system clock of the component.

25. The component according to claim 14, wherein the clock phases of the clock domains of the input flip-flops and the output flip-flops are different from the clock phase of a system clock of the component.

26. The component according to claim 12, wherein first delay elements for adjusting the hold time are disposed ahead of the input flip-flops in the input block.

27. The component according to claim 12, wherein second delay elements for adjusting the clock skew are disposed after the input flip-flops and ahead of the remainder core in the input block.

28. The component according to claim 12, wherein third delay elements for adjusting the min-clock-to-output are disposed in the output block.
